(19) United States
(12) Patent Application Publication
(10) Pub. No.: US 2025/0309168 A1
(43) Pub. Date: Oct. 2, 2025

(54) SEMICONDUCTOR PACKAGE HAVING AN ARRAY OF MULTI-SIZED INTERCONNECT STRUCTURES

(71) Applicant: Micron Technology, Inc., Boise, ID (US)

(72) Inventor: Chao Wen WANG, Taichung (TW)

(21) Appl. No.: 19/058,518

(22) Filed: Feb. 20, 2025

Related U.S. Application Data
(60) Provisional application No. 63/572,026, filed on Mar. 29, 2024.

(51) Int. Cl. H01L 23/00; H01L 25/07; H10B 80/00

(52) U.S. Cl. CPC H01L 24/14; H01L 24/03; H01L 24/05; H01L 24/11; H01L 24/13; H01L 24/16; H01L 25/074; H01L 2224/0347; H01L 2224/0401; H01L 2224/05572; H01L 2224/11462; H01L 2224/1147; H01L 2224/11849; H01L 2224/13022; H01L 2224/13082; H01L 2224/13124; H01L 2224/13139; H01L 2224/13144; H01L 2224/13147; H01L 2224/13155; H01L 2224/1403; H01L 2224/14051; H01L 2224/14104; H01L 2224/16145; H01L 2225/06513; H10B 80/00

(57) ABSTRACT

Implementations described herein relate to various semiconductor device assemblies. In some implementations, an apparatus includes an interconnect array structure including a first metallization layer having a first pad structure, a second metallization layer having a second pad structure, and at least one dielectric layer between the first metallization layer and the second metallization layer. The apparatus includes a first pillar bump structure connected with the first pad structure, where the first pillar bump structure includes a first bump structure having a first volume. The apparatus includes a second pillar bump structure connected with the second pad structure, where the second pillar bump structure includes a second bump structure having a second volume that is greater than the first volume.

### CROSS-REFERENCE TO RELATED APPLICATION

This Patent Application claims priority to U.S. Provisional Patent Application No. 63/572,026, filed on Mar. 29, 2024, entitled “SEMICONDUCTOR PACKAGE HAVING AN ARRAY OF MULTI-SIZED INTERCONNECT STRUCTURES,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor package having an array of multi-sized interconnect structures.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pad structures, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), an accelerated processing unit (APU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A and 1B are diagrams of an example apparatus that may be manufactured using techniques described herein.

FIG. 2 is a diagram of an example memory device that may be manufactured using techniques described herein.

FIG. 3 is a flowchart of an example method of forming an integrated assembly or memory device having an array of multi-sized interconnect structures described herein.

FIG. 4 is a flowchart of an example method of forming an integrated assembly or memory device having an array of multi-sized interconnect structures described herein.

FIG. 5 is a flowchart of an example method of forming an integrated assembly or memory device having an array of multi-sized interconnect structures described herein.

FIGS. 6A through 6G are diagrammatic views showing formation of an array of multi-sized interconnect structures described at stages of an example process described herein.

### DETAILED DESCRIPTION

A semiconductor die is often formed with external interconnect structures for connecting the semiconductor die with another semiconductor die. To facilitate high-density interconnections, the interconnect structures may include pillar bump structures. The pillar bump structures play a pivotal role in enabling high-density interconnections between the semiconductor die and the other semiconductor die. By allowing for a finer pitch and reduced spacing between electrical traces and/or connections, the pillar bump structures may elevate the overall performance, speed, and reliability of a semiconductor die package including the semiconductor die.

A semiconductor die may include a single metallization layer (e.g., one of the metallization layers in a backend of line (BEOL) region of the semiconductor die), upon which an array of pillar bump structures is formed. Furthermore, and in some cases, the array of pillar bump structures may have bump structures of a same approximate size regardless of an electrical signaling function (e.g., a power function, a ground function, a clocking function, or a data function). As pitches and spacing between electrical traces and/or connections reduce with miniaturization, a reduction in the size of each of the array of pillar bump structures may reduce a volume of solder included in each bump. For a pillar bump structure conducting a high electrical current (e.g., a power function or a ground function), a bump structure with a reduced volume of solder may have a shortened useable lifetime (e.g., an electromigration lifetime) such that the pillar bump structure fails to satisfy a reliability threshold.

To improve the reliability and satisfy the reliability threshold, an array of pillar bump structures of different sizes (e.g., including bump structures of different volumes) may be used. However, based on constraints associated with using one metallization layer and in order to satisfy bonding thresholds for joining the semiconductor die with another semiconductor die (e.g., co-planarity thresholds and/or die-to-die bond line thresholds for the bump structures), techniques to form the array may include using multiple lithography, etching, and deposition cycles. For a semiconductor package that includes the semiconductor die, the bonding thresholds, in combination with the multiple lithography, etching, and deposition cycles prompted by use of one of the metallization layers, may cause yield losses during fabrication (e.g., cause quality defects) and/or shorten a useful lifetime (e.g., cause reliability defects).

Some implementations described herein include a semiconductor package having a semiconductor die that includes an array of multi-sized interconnect structures.

The array of multi-sized interconnect structures (e.g., an array of multi-sized pillar bump structures) may be formed on two or more metallization layers of the semiconductor die (e.g., pad structures in the two or more metallization layers). In some implementations, forming the multi-sized interconnect structures on the two or more metallization layers facilitates different heights and/or critical dimensions of pillars to accommodate bump structures having different widths, diameters, and/or volumes. Forming the array of multi-sized interconnect structures on the two or more metallization layers may increase a likelihood of the array multi-sized interconnect structures satisfying one or more thresholds related to an electromigration lifetime, a coplanarity for joining the semiconductor die with another semiconductor die, a bond line thickness for joining the semiconductor die with another semiconductor die, and/or a size of the semiconductor package.

In this way, and in comparison to another semiconductor package including an array of multi-sized interconnect structures formed on a single metallization layer, the semiconductor die package may realize an increased quality, an increased reliability, and/or a reduced size. By increasing the quality, increasing the reliability, and/or reducing the size of the semiconductor package, an amount of resources used to support a market consuming the semiconductor package (e.g., raw materials, labor, semiconductor manufacturing tools, and/or computing resources) may be reduced.

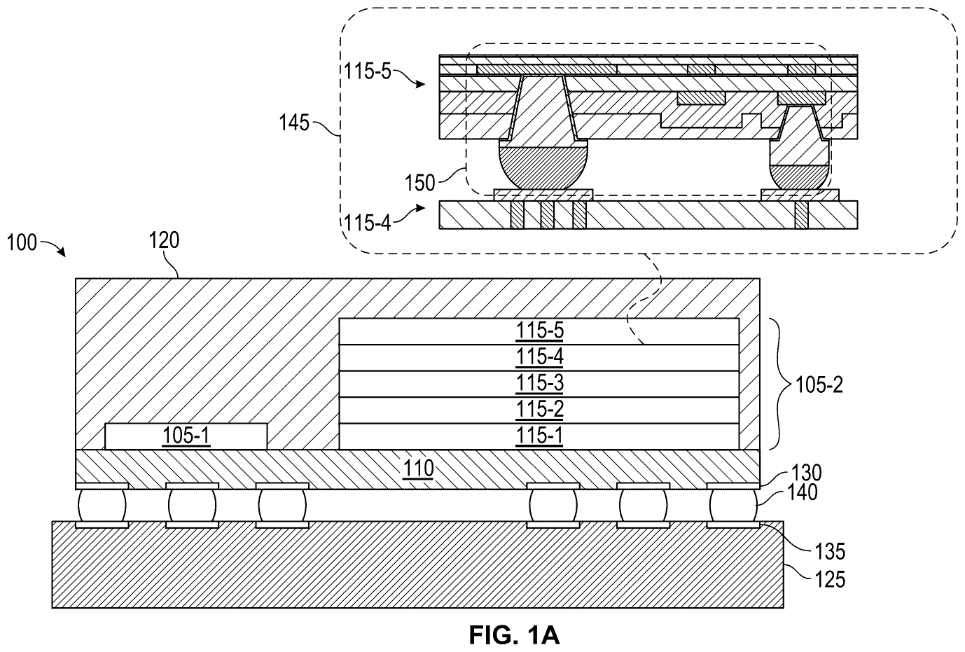

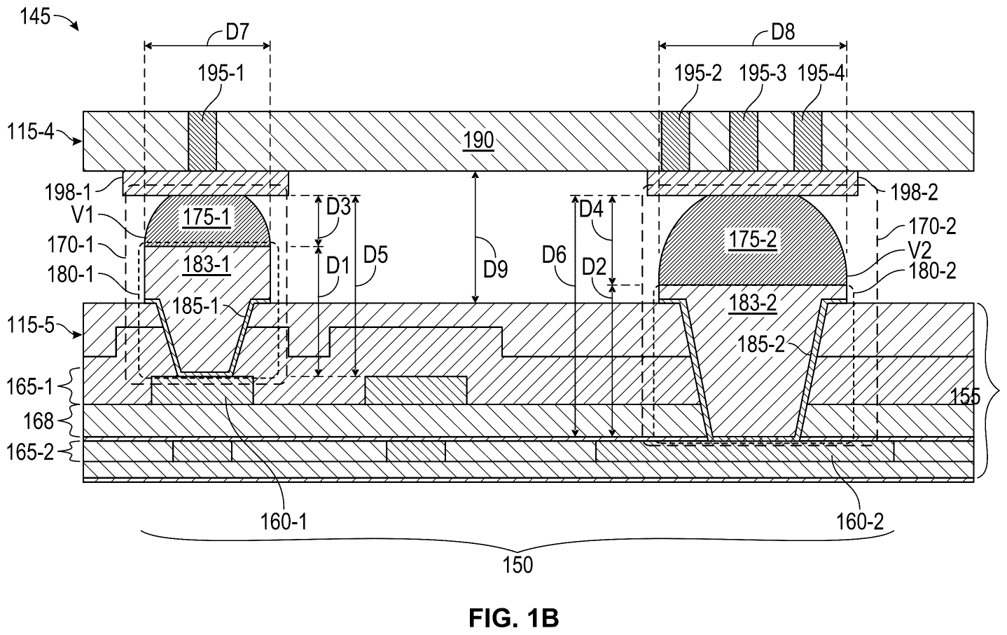

FIGS. 1A and 1B are diagrams of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM), a high bandwidth memory (HBM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1A, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-4. In some implementations, the integrated circuit 105 and/or the dies 115 are “chiplets” (e.g., integrated circuitry and/or semiconductor dies that have specific functionalities, are modular, and can be mixed with other integrated circuitry and/or other semiconductor dies). Furthermore, the substrate 110 may take a number of forms and/or include a combination of features. For example, and in some implementations, the substrate 110 is a silicon interposer or a ceramic interposer. Additionally, or alternatively and in some implementations, the substrate 110 includes one or more redistribution layers (RDL), electrical traces, and/or interconnects (e.g., TSVs). Additionally, or alternatively, and in some implementations, the substrate 110 is a combination of a silicon interposer and an organic substrate. Additionally, or alternatively and in some implementations, the substrate 110 includes active integrated circuitry and/or is a semiconductor die (e.g. a GPU or an APU).

As shown in FIG. 1A, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. FIG. 1A shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pad structures) of the substrate 110 are electrically connected to electrical contacts 135 (e.g., bond pad structures) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pad structures (e.g., bond pad structures) that are electrically connected to corresponding electrical pad structures (e.g., bond pad structures) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As shown in the magnified view of FIG. 1A, and as described greater detail in connection with FIG. 1B and elsewhere herein, two or more dies 115 (e.g., the dies 115-4 and 115-5) may join together in a bond region 145. As part of the bond region 145, the die 115-5 may include an interconnect array structure 150 that includes two or more pillar bump structures having different critical dimensions (e.g., different sizes).

As shown in FIG. 1B, portions of the interconnect array structure 150 may be within a multi-layer stack 155 of the die 115-5. The multi-layer stack 155 (e.g., a passivation region) may include one or more interspersed layers of dielectric materials such as silicon nitride (e.g., Si₃Ni₄), silicon dioxide (SiO₂), aluminum dioxide (Al₂O₃), or other suitable dielectric materials, among other examples. In some implementations, the multi-layer stack 155 is part of a backend of line (BEOL) region of the die 115-5.

As shown in FIG. 1B, the interconnect array structure 150 includes one or more pad structures 160 (e.g., the pad structures 160-1 and 160-2) within the multi-layer stack 155. Each of the pad structures 160 may include a conductive material. The conductive material of each of the pad structures 160 may comprise, consist of, or consist essentially of nickel (Ni), copper (Cu), aluminum (Al), gold (Au), tin (Sn), silver (Ag), or another suitable conductive material, among other examples. In some implementations, each of the pad structures 160 may include a same conductive material. Alternatively, and in some implementations, two or more of the pad structures 160 may include different conductive materials.

Within the multi-layer stack 155, and as shown in FIG. 1B, the pad structures 160 are dispersed among at least two metallization layers 165. For example, and as shown in FIG. 1B, the pad structure 160-1 may be part of a metallization layer 165-1 and the pad structure 160-2 may be part of the metallization layer 165-2, where the metallization layer 165-1 and the metallization layer 165-2 are separated by the dielectric layer 168. Furthermore, and in some implementations, an area encompassed by the pad structure 160-1 is greater than an area encompassed by the pad structure 160-2 (e.g. the pad structure 160-1 and the pad structure 160-2 may have different sized footprints that encompass different sized areas).

As further shown in FIG. 1B, the interconnect array structure 150 includes two or more pillar bump structures 170 (e.g., micro-pillar bump structures) that each include a bump structure 175 that is over and/or on a pillar structure 180 (e.g., a micro-pillar structure). In some implementations, each of the pillar bump structures 170 includes a conductive layer 183 and a seed layer 185.

For example, the interconnect array structure 150 includes the pillar bump structure 170-1 that includes the bump structure 175-1 that is over and/or on the pillar structure 180-1. The pillar structure 180-1 may include a conductive layer 183-1 that is over and/or on the seed layer 185-1, where the seed layer 185-1 is over and/or on the pad structure 160-1. Additionally, or alternatively, the pillar structure 180-1 may include nickel (Ni), copper (Cu), gold (Au), tin (Sn), silver (Ag), or another suitable conductive material.

Additionally, the interconnect array structure 150 includes the pillar bump structure 170-2 that includes the bump structure 175-2 that is over and/or on the pillar structure 180-2. The pillar structure 180-2 may include a conductive layer 183-2 that is over and or on the seed layer 185-3, where the seed layer 185-2 is over and/or on the pad structure 160-2. Additionally, or alternatively, the pillar structure 180-2 may include nickel (Ni), copper (Cu), gold (Au), tin (Sn), silver (Ag), a solder alloy, or another suitable conductive material.

The bump-structures 175-1 and/or 175-2 may include a solder-based material that is conductive. A solder-based material is a material which contains solder, which is a low-melting-point metal alloy (e.g., a metal alloy that liquefies at less than 250 degrees Celsius) that is used to join or bond other metals together. The solder is applied in a molten state and solidifies upon cooling, creating a strong and conductive bond between the joined materials. The solder-based material of the bump structures 175-1 and/or 175-2 may comprise, consist of, or consist essentially of a tin-silver-copper (Sn—Ag—Cu) alloy, a tin-copper (Sn-u) alloy, a tin-bismuth (Sn—Bi) alloy, or another suitable solder-based material that is conductive, among other examples. In some implementations, the bump structures 175-1 and 175-2 include a same solder-based material. In some implementations, the bump structures 175-1 and 175-2 include different solder-based materials.

The conductive layers 183-1 and/or 183-2 may include a conductive material. The conductive material of the conductive layers 183-1 and/or 183-2 may comprise, consist of, or consist essentially of nickel (Ni), copper (Cu), gold (Au), tin (Sn), or another suitable conductive material, among other examples. In some implementations, the conductive layers 183-1 and 183-2 include a same conductive material. In some implementations, the conductive layers 183-1 and 183-2 include different conductive materials.

The seed layers 185-1 and/or 185-2 may include a conductive material. The conductive material of the seed layers 185-1 and/or 185-2 may comprise, consist of, or consist essentially of nickel (Ni), copper (Cu), gold (Au), tin (Sn), silver (Ag), or another suitable conductive material, among other examples. In some implementations, the seed layers 185-1 and 185-2 include a same conductive material. In some implementations, the seed layers 185-1 and 185-2 include different conductive materials.

One or more corresponding features of the pillar bump structures 170 may have different critical dimensions and/or sizes (e.g., have different widths, heights, and/or volumes). For example, and as shown in FIG. 1B, a height D1 that the pillar structure 180-1 extends above the pad structure 160-1 may be less than a height D2 that the pillar structure 180-2 extends above the pad structure 160-2. Additionally, or alternatively, a height D3 that the bump structure 175-1 extends above the pillar structure 180-1 may be less than a height D4 that the bump structure 175-2 extends above the pillar structure 180-2. Additionally, or alternatively, an overall height D5 that the pillar bump structure 170-1 extends above the pad structure 160-1 may be less than an overall height D6 that the pillar bump structure 170-2 extends above the pad structure 160-2. Additionally, or alternatively, a width D7 of the pillar structure 180-1 (and/or the bump structure 175-1) may be less than a width D8 of the pillar structure 180-2 (and/or the bump structure 175-2).

Based on the height D3 and the width D7 of the bump structure 175-1 relative to the height D4 and the width D8 of the bump structure 175-2, a volume V1 of the bump structure 175-1 may be less than a volume V2 of the bump structure 175-2. As a result, an electromigration lifetime of the pillar bump structure 170-1 (e.g., including the bump structure 175-1) may be less than an electromigration lifetime of the pillar bump structure 170-2 (e.g., including the bump structure 175-2). In other words, the pillar bump structure 170-1 may be a structure that is more suitable for low power usage (e.g., a data signal connection structure or a clocking signal connection structure) than the pillar bump structure 170-2, which may be a structure that is more suitable for high power usage (e.g., a power signal connection structure or a ground signal connection structure).

As shown in FIG. 1B, the pillar bump structure 170-1 is over and/or on the metallization layer 165-1 (e.g., a first metallization layer) and the pillar bump structure 170-2 is over and/or on the metallization layer 165-2 (e.g., a second metallization layer) that is directly below the metallization layer 165-1. However, and based on a targeted critical dimension or difference in critical dimensions, a pillar bump structure may be over and/or on another metallization layer that is below the metallization layers 165-1 and 165-2 (e.g., a third metallization layer, a fourth metallization layer, and so on). Additionally, or alternatively, combinations of pillar bump structures may be formed over and/or on more than two metallization layers based on different targeted critical dimensions or differences in critical dimensions.

As further shown in 1B, the die 115-4 includes a bulk semiconductor region 190. The bulk semiconductor region 190 may include a semiconductive material. The semiconductive material of the bulk semiconductor region 190 may comprise, consist of, or consist essentially of silicon (e.g., polycrystalline silicon (Si)), among other examples. Alternatively, the semiconductive material of the bulk semiconductor region 190 may comprise, consist of, or essentially consist of germanium (Ge), gallium arsenide (GaAs), allium nitride (GaN), silicon carbide (SiC), or another suitable semiconductive material, among other examples.

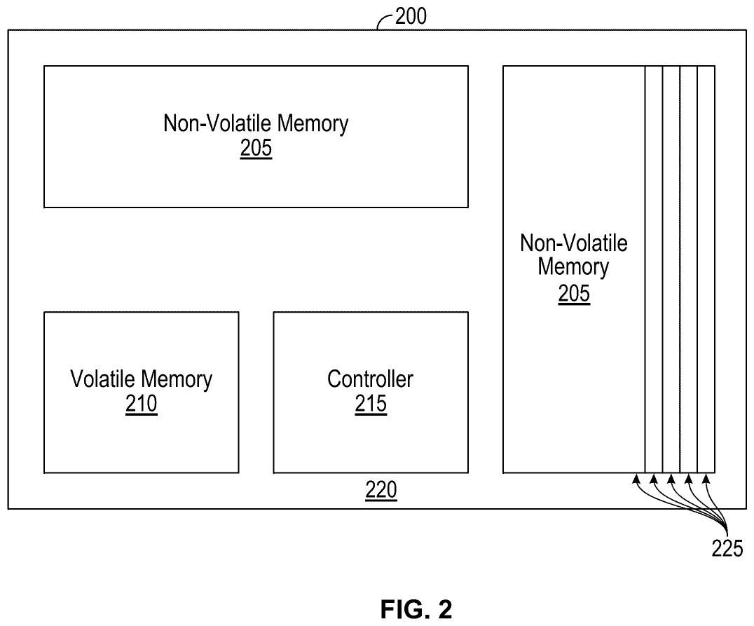

The die 115-1 further includes interconnect structures 195 that connect with corresponding pad structures 198. For example, the die includes the interconnect structure 195-1 that connects with the pad structure 198-1, and the interconnect structures 195-2 through 195-4 that connect with the pad structure 198-2. As shown in FIG. 2, an outer surface of the pad structure 198-1 joins with the bump structure 175-1 of the pillar bump structure 180-1, and an outer surface of the pad structure 198-2 joins with the bump structure 175-2 of the pillar bump structure 180-2. In some implementations, the outer surfaces of the pad structures 198-1 and 198-2 are substantially coplanar.

The interconnect structures 195 (e.g., through silicon vias or TSVs) may each include a conductive material. The conductive material of the interconnect structures 195 may comprise, consist of, or consist essentially of copper (Cu), tungsten (W), or another suitable conductive material, among other examples.

The pad structures 198 (e.g., under bump metal structures, or UBMs) include a conductive material. The conductive material of the pad structures 198 may comprise, consist of, or consist essentially of titanium (Ti), nickel (Ni), copper (Cu), gold (Au), palladium (Pd), copper (Cu), tungsten (W), or another suitable conductive material, among other examples. In some implementations, the pad structures 198-1 and 198-2 include a same conductive material. In some implementations, the pad structures 198-1 and 198-2 include different conductive materials.

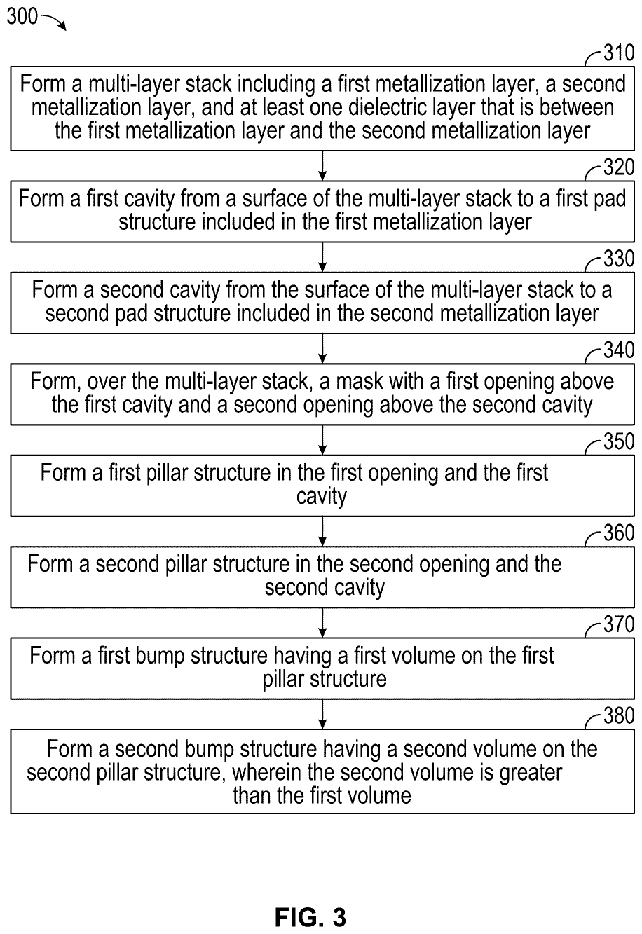

As further shown in FIG. 1B, a distance D9 separates the dies 115-5 and 115-4. As described in greater detail in connection with FIGS. 3-6G, techniques to fabricate the interconnect array structure 150 may control dimensions associated with the interconnect array structure 150 to satisfy one or more thresholds (e.g., overall height thresholds of the pillar bump structures 170 and/or co-planarity thresholds of the bump structures 175) impacting the distance D9 (e.g., a bond line thickness).

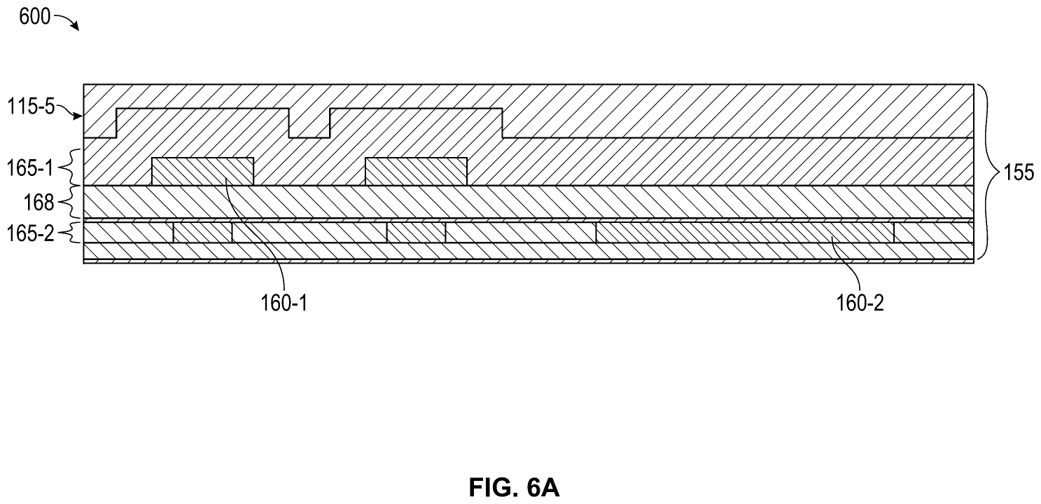

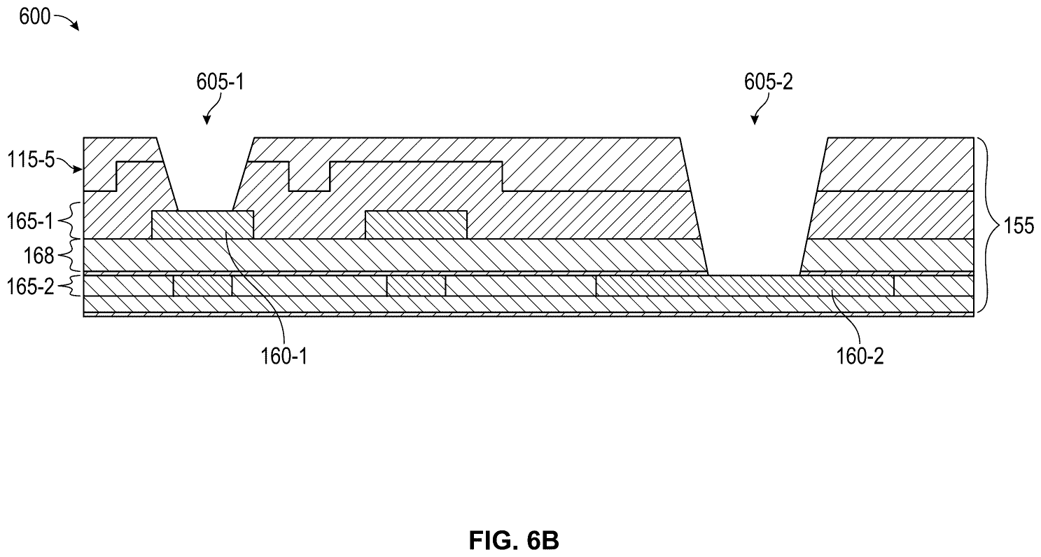

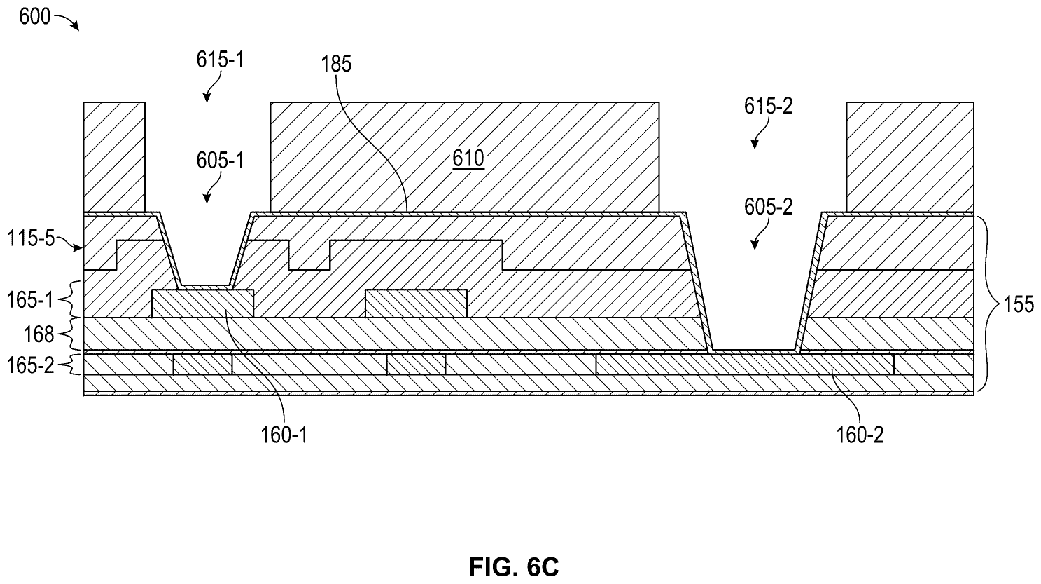

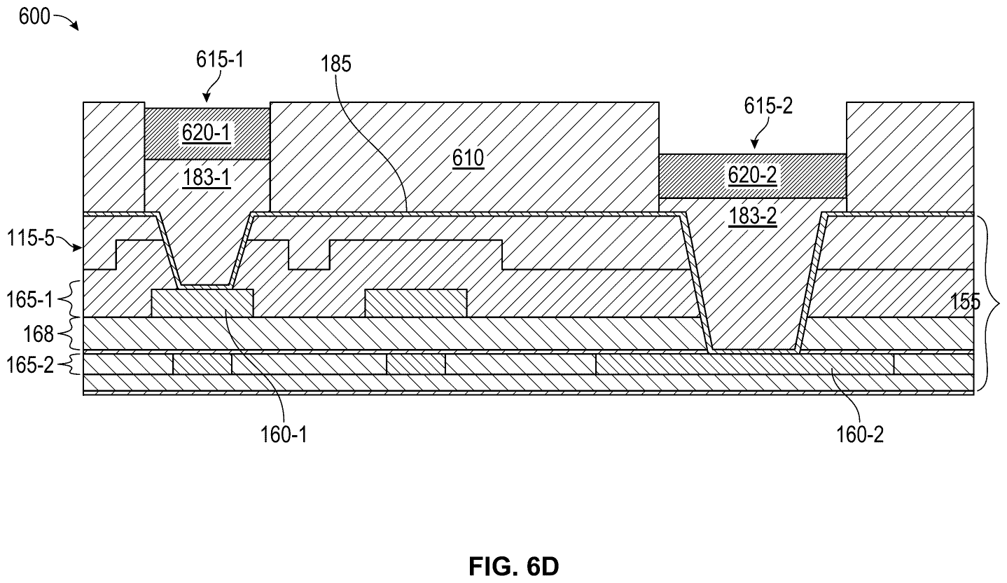

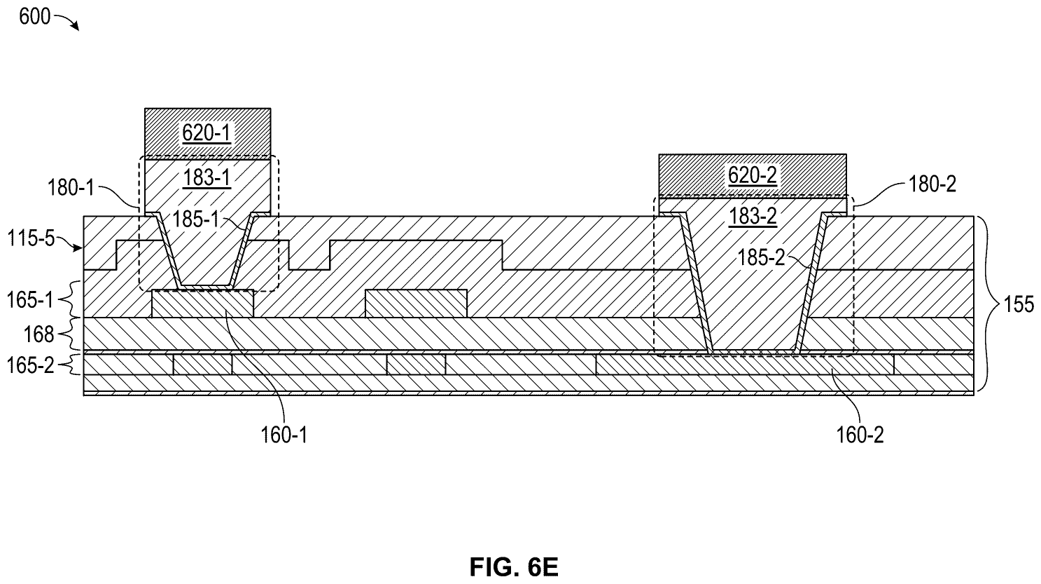

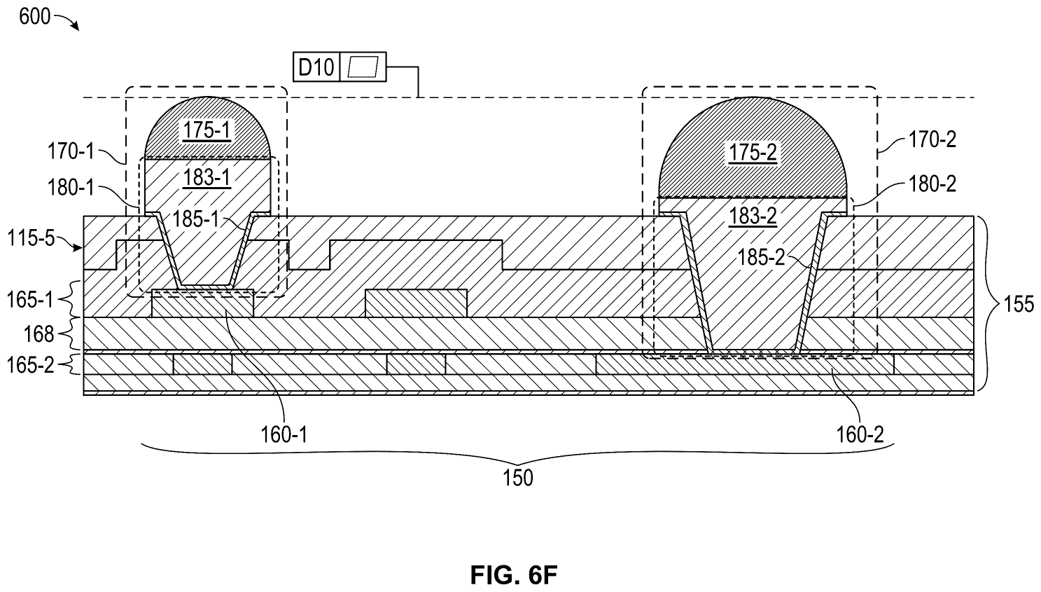

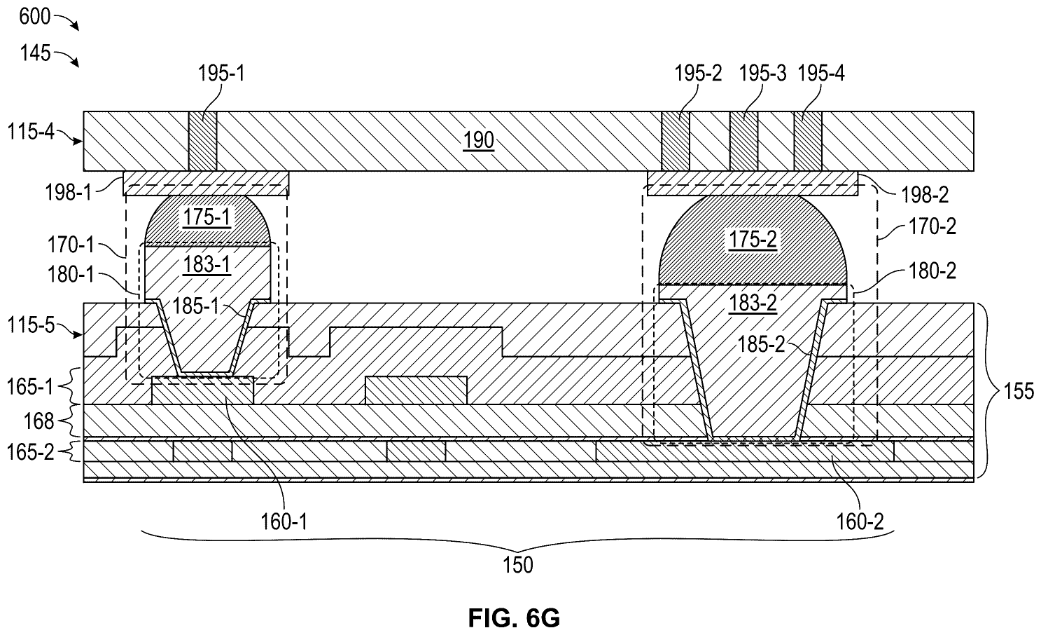

A semiconductor package (e.g., the apparatus 100) having the interconnect array structure 150 including the pillar bump structures 170-1 and 170-2 on the metallization layers 165-1 and 165-2 may enable one or more thresholds related to a signaling performance, a size of the semiconductor package, and/or an electromigration lifetime of the semiconductor die package to be satisfied. As an example, the semiconductor package may be formed such that the distance D9 (e.g., the bond line thickness) impacting trace lengths is less than approximately 15 microns (μm) to satisfy one or more signaling thresholds (e.g., inductance and/or impedance thresholds impacting a parasitic performance of the semiconductor package) between the die 115-5 and the die 115-4. Additionally, or alternatively, critical dimensions (e.g., the widths D7 and D8) of the pillar bump structures 170-1 and 170-2 may be less than approximately 20 μm to reduce a pitch and/or spacing to satisfy one or more size thresholds related of the semiconductor package. Additionally, or alternatively, volumes of the bump structures 175-1 and 175-2 (e.g., V1 and V2) may be different, to satisfy one or more thresholds related to electromigration lifetime of the pillar bump structures 170-1 and 170-2. Furthermore, and as described in greater detail in connection with FIGS. 6A-6G, formation of the pillar bump structures 170-1 and 170-2 over and/or the pad structure 160-1 and 160-2 may require a single photolithography and etching operation to form cavities for the conductive layers 183-1 and 183-2.

In this way, the semiconductor package may realize an increased quality and/or reliability in comparison to another semiconductor package including an array of multi-sized interconnect structures formed on a single metallization layer of a semiconductor die. Additionally, or alternatively, the semiconductor package may realize a reduced size. By increasing the quality and/or reliability of the semiconductor package, and/or reducing the size of the semiconductor package, an amount of resources used to support a market consuming the semiconductor package (e.g., raw materials, labor, semiconductor manufacturing tools, and/or computing resources) may be reduced.

As indicated above, FIGS. 1A and 1B are provided as an example. Other examples may differ from what is described with regard to FIGS. 1A and 1B.

FIG. 2 is a diagram of an example memory device 200 that may be manufactured using techniques described herein. The memory device 200 is an example of the apparatus 100 described above in connection with FIGS. 1A and 1B. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1A.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

As described in connection with FIGS. 1A, 1B, and 2, and in some implementations, an apparatus (the apparatus 100, the semiconductor die 115-5, or the memory device 200, among other examples) includes an interconnect array structure (e.g., the interconnect array structure 150). The interconnect array structure includes a first metallization layer (e.g., the metallization layer 165-1) including a first pad structure (e.g., the pad structure 160-1) and a second metallization layer (e.g., the metallization layer 165-2) including a second pad structure (e.g., the pad structure 160-2), and at least one dielectric layer (e.g., the dielectric layer 168) between the first metallization layer and the second metallization layer. The interconnect array structure further includes a first pillar bump structure (e.g., the pillar bump structure 170-1) that is connected with the first pad structure and includes a first bump structure (e.g., the bump structure 175-1) having a first volume (e.g., the volume V1). The interconnect array structure further includes a second pillar bump structure (e.g., the pillar bump structure 170-2) that is connected with the second pad structure and that includes a second bump structure (e.g., the bump structure 175-2) having a second volume (e.g., the volume V2) that is greater than the first volume.

Additionally or alternatively, and as described in connection with FIGS. 1A, 1B, and 2, in some implementations an apparatus (the apparatus 100 or the memory device 200, among other examples) includes a first semiconductor die (e.g., the die 115-5) including a multi-layer stack (e.g., the multi-layer stack 155), a first pillar bump structure (e.g., the pillar bump structure 170-1) that extends away from a first metallization layer (e.g., the metallization layer 165-1) in the multi-layer stack to a first height (e.g., the height D5), and a second pillar bump structure (e.g., the pillar bump structure 170-2) that extends away from a second metallization layer (e.g., the metallization layer 175-2) in the multi-layer stack to a second height (e.g., the height D6), where the second height is greater than the first height. The apparatus further includes a second semiconductor die (e.g., the semiconductor die 115-4) joined with the first semiconductor die. The second semiconductor die includes a first pad structure (e.g., the pad structure 198-1) having a first outer surface that joins with the first pillar bump structure and a second pad structure (e.g., the pad structure 198-2) having a second outer surface that joins with the second pillar bump structure.

FIG. 3 is a flowchart of an example method 300 of forming an integrated assembly or memory device having an array of multi-sized interconnect structures described herein (e.g., the interconnect array structure 150). In some implementations, and as described in greater detail in connection with FIGS. 6A though 6G, one or more process blocks of FIG. 3 may be performed by various semiconductor manufacturing equipment. Such semiconductor manufacturing equipment may be located at a semiconductor wafer foundry, an outsourced assembly and testing (OSAT) facility, an original equipment manufacturing (OEM) facility, or another suitable manufacturing facility.

As shown in FIG. 3, the method 300 may include forming a multi-layer stack (e.g., the multi-layer stack 155) including a first metallization layer (e.g., the metallization layer 165-1), a second metallization layer (e.g., the metallization layer 165-2), and at least one dielectric layer (e.g., the dielectric layer 168) that is between the first metallization layer and the second metallization layer (block 310). As further shown in FIG. 3, the method 300 may include forming a first cavity from a surface of the multi-layer stack to a first pad structure (e.g., the pad structure 160-1) included in the first metallization layer (block 320). As further shown in FIG. 3, the method 300 may include forming a second cavity from the surface of the multi-layer stack to a second pad structure (e.g., the pad structure 160-2) included in the second metallization layer (block 330). As further shown in FIG. 3, the method 300 may include forming, over the multi-layer stack, a mask with a first opening above the first cavity and a second opening above the second cavity (block 340). As further shown in FIG. 3, the method 300 may include forming a first pillar structure (e.g., the pillar structure 180-1) in the first opening and the first cavity (block 350). As further shown in FIG. 3, the method 300 may include forming a second pillar structure (e.g., the pillar structure 180-2) in the second opening and the second cavity (block 360). As further shown in FIG. 3, the method 300 may include forming a first bump structure (e.g. the bump structure 175-1) having a first volume (e.g., the volume V1) on the first pillar structure (block 370). As further shown in FIG. 3, the method 300 may include forming a second bump structure (e.g., the bump structure 175-2) having a second volume (e.g., the volume V2) on the second pillar structure, wherein the second volume is greater than the first volume (block 380).

The method 300 may include additional aspects, such as any single aspect or any combination of aspects described below and/or in connection with one or more other methods described elsewhere herein.

In a first aspect, forming the first pillar structure includes forming a seed layer (e.g., the seed layer 160-1) in the first cavity.

In a second aspect, alone or in combination with the first aspect, forming the second pillar structure includes forming a seed layer (e.g., the seed layer 160-2) in the second cavity.

In a third aspect, alone or in combination with one or more of the first and second aspects, forming the first pillar structure and the second pillar structure includes forming the pillar structure and the second pillar structure using at least one electroplating operation that simultaneously forms respective portions of the first pillar structure and the second pillar structure.

In a fourth aspect, alone or in combination with one or more of the first through third aspects, simultaneously forming the respective portions of the first pillar structure and the second pillar structure includes simultaneously forming the respective portions (e.g., the conducive layer 183-1 and the conductive layer 183-2) at different electroplating growth rates.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the array of multi-sized interconnect structures, an integrated assembly that includes the array of multi-sized interconnect structures, any part described herein of the array of multi-sized interconnect structures, and/or any part described herein of an integrated assembly that includes the array of multi-sized interconnect structures. For example, the method 300 may include forming one or more parts of a die (e.g., the die 115-5), an apparatus (e.g., the apparatus 100), or a memory device (e.g., the memory device 200).

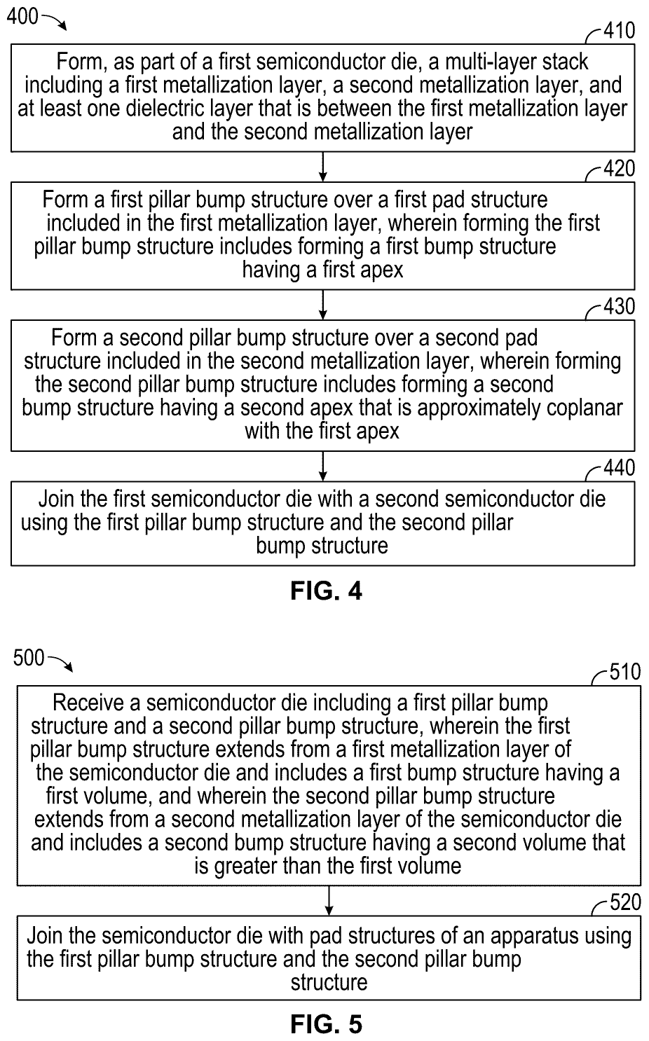

FIG. 4 is a flowchart of an example method 400 of forming an integrated assembly or memory device having an array of multi-sized interconnect structures described herein (e.g., the interconnect array structure 150). In some implementations, and as described in greater detail in connection with FIGS. 6A though 6G, one or more process blocks of FIG. 4 may be performed by various semiconductor manufacturing equipment. Such semiconductor manufacturing equipment may be located at a semiconductor wafer foundry, an OSAT facility, an OEM facility, or another suitable manufacturing facility.

As shown in FIG. 4, the method 400 may include forming, as part of a first semiconductor die (e.g., the die 115-5), a multi-layer stack (e.g., the multi-layer stack 155) including a first metallization layer (e.g., the metallization layer 165-1), a second metallization layer (e.g., the metallization layer 165-2), and at least one dielectric layer (e.g., the dielectric layer 168) that is between the first metallization layer and the second metallization layer (block 410). As further shown in FIG. 4, the method 400 may include forming a first pillar bump structure (e.g., the pillar bump structure 170-1) over a first pad structure (e.g., the pad structure 160-1) included in the first metallization layer, where forming the first pillar bump structure includes forming a first bump structure (e.g., the bump structure 175-1) having a first apex (block 420). As further shown in FIG. 4, the method 400 may include forming a second pillar bump structure (e.g., the pillar bump structure 170-2) over a second pad structure (e.g., the pad structure 160-2) included in the second metallization layer, where forming the second pillar bump structure includes forming a second bump structure (e.g., the bump structure 175-2) having a second apex that is approximately coplanar with the first apex (block 430). As further shown in FIG. 4, the method 400 may include joining the first semiconductor die with a second semiconductor die (e.g., the die 115-4) using the first pillar bump structure and the second pillar bump structure (block 440).

The method 400 may include additional aspects, such as any single aspect or any combination of aspects described below and/or in connection with one or more other methods described elsewhere herein.

In a first aspect, forming the second pillar bump structure includes forming at least a portion of a pillar structure (e.g., at least a portion of the pillar structure 180-2) in a cavity that penetrates through the dielectric layer.

In a second aspect, alone or in combination with the first aspect, forming the first bump structure and the second bump structure includes simultaneously depositing a solder-based material for the first bump structure and the second bump structure using an electroplating operation.

In a third aspect, alone or in combination with one or more of the first and second aspects, forming the first bump structure and the second bump structure includes simultaneously forming the first apex and the second apex using a reflow operation.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the array of multi-sized interconnect structures, an integrated assembly that includes the array of multi-sized interconnect structures, any part described herein of the array of multi-sized interconnect structures, and/or any part described herein of an integrated assembly that includes the array of multi-sized interconnect structures. For example, the method 400 may include forming one or more parts of a die (e.g., the die 115-5), an apparatus (e.g., the apparatus 100), or a memory device (e.g., the memory device 200).

FIG. 5 is a flowchart of an example method 500 of forming an integrated assembly or memory device having an array of multi-sized interconnect structures described herein (e.g., the interconnect array structure 150). In some implementations, one or more process blocks of FIG. 5 may be performed by various semiconductor manufacturing equipment. Such semiconductor manufacturing equipment may be located at a semiconductor wafer foundry, an OSAT facility, an OEM facility, or another suitable manufacturing facility.

As shown in FIG. 5, the method 500 may include receiving a semiconductor die (e.g., the die 115-5) including a first pillar bump structure (e.g., the pillar bump structure 170-1) and a second pillar bump structure (e.g., the pillar bump structure 170-2), where the first pillar bump structure extends from a first metallization layer (e.g., the metallization layer 160-1) of the semiconductor die and includes a first bump structure (e.g., the bump structure 175-1) having a first volume (e.g., the volume V1), and where the second pillar bump structure extends from a second metallization layer (e.g., the metallization layer 160-2) of the semiconductor die and includes a second bump structure (e.g., the bump structure 175-2) having a second volume (V2) that is greater than the first volume (block 510). As further shown in FIG. 5, the method 500 may include joining the semiconductor die with pad structures of an apparatus (the pad structures 198-1 and 198-2 of the die 115-4, pad structures included in the memory device 200, or pad structures included in a printed circuit board (PCB) or another substrate, among other examples), using the first pillar bump structure and the second pillar bump structure (block 520).

The method 500 may include additional aspects, such as any single aspect or any combination of aspects described below and/or in connection with one or more other methods described elsewhere herein.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the array of multi-sized interconnect structures, an integrated assembly that includes the array of multi-sized interconnect structures, any part described herein of the array of multi-sized interconnect structures, and/or any part described herein of an integrated assembly that includes the array of multi-sized interconnect structures. For example, the method 500 may include forming one or more parts of a die (e.g., the die 115-5), an apparatus (e.g., the apparatus 100), or a memory device (e.g., the memory device 200).

FIGS. 6A through 6G are diagrammatic views showing formation of an array of multi-sized interconnect structures (e.g., the interconnect array structure 150) described at stages of an example process 600 described herein. In some implementations, the process 600 described below in connection with FIGS. 6A through 6G may correspond to the method 300, one or more blocks of the method 300, the method 400, one or more blocks of the method 400, the method 500, and/or one or more blocks of the method 500. However, the process described below is an example, and other example processes may be used to form the interconnect array structure 150, an integrated assembly that includes the interconnect array structure 150, and/or one or more parts of an integrated assembly including the interconnect array structure 150.

As shown in FIG. 6A, the process 600 includes forming the multi-layer stack 155. Forming the multi-layer stack 155 may include forming a combination of layers of dielectric materials interspersed with layers of conductive materials, including the dielectric layer 168 between the metallization layers 165-1 and 165-2. In some implementations, techniques to form a layer of the multi-layer stack 155 include a semiconductor manufacturing tool (e.g., a deposition tool) performing a deposition operation. Additionally, or alternatively and in some implementations, techniques to form a layer of the multi-layer stack 155 include a combination of semiconductor manufacturing tools (e.g., a photolithography exposure tool, a developer tool, and an etch tool) performing one or more patterning and etching operations to remove portions of a layer included in the multi-layer stack 155.

As shown in FIG. 6B, the process 600 includes forming cavities 605-1 and 605-2. Forming the cavity 605-1 may include forming the cavity 605-1 from a top surface of the multi-layer stack 155 to the pad structure 160-1. Additionally, or alternatively, forming the cavity 605-2 may include forming the cavity 605-2 from the top surface of the multi-layer stack 155 to the pad structure 160-2. In some implementations, techniques to form the cavities 605-1 and 605-2 include a combination of semiconductor manufacturing tools (e.g., a coating tool, a photolithography exposure tool, a developer tool, and an etch tool) performing one or more patterning and etching operations to remove portions of the multi-layer stack 155 to expose the pad structures 160-1 and 160-2.

As shown in FIG. 6C, the process 600 includes forming the seed layer 185 over and/or on the multi-layer stack 155 and over and/or along contours of the cavities 605-1 and 605-2. In some implementations, techniques to form the seed layer 185 include a semiconductor manufacturing tool (e.g., a deposition tool) performing a deposition operation to form the seed layer 185.

As further shown in FIG. 6C, the process 600 includes forming a mask structure 610 (e.g., a patterned layer of a photoresist material) over the multi-layer stack 155. Forming the mask structure 610 may include forming an opening 615-1 over the cavity 605-1 and an opening 615-2 over the cavity 605-2. In some implementations, techniques to form the mask structure 610 include a combination of semiconductor manufacturing tools (e.g., a coating tool, a photolithography exposure tool, and a developer tool) performing one or more operations to deposit the mask structure 615 and pattern the openings 615-1 and 615-2.

As shown in FIG. 6D, the process 600 includes forming the conductive layer 183-1 (e.g., in the cavity 605-1 and the opening 615-1) and the conductive layer 183-2 (e.g., in the cavity 605-2 and the opening 615-2). In some implementations, techniques to form the conductive layers 183-1 and 183-2 include a semiconductor manufacturing tool (e.g., a deposition tool) performing an electroplating operation that simultaneously forms the conductive layers 183-1 and 183-2.

In some implementations and based on a difference in sizes and/or aspect ratios (e.g., a width versus a depth) of the cavities 605-1 and 605-2, the electroplating operation simultaneously forms respective portions of the conductive layers 183-1 and 183-2 at different electroplating growth rates. Forming the respective portions of the conductive layers 183-1 and 183-2 at different growth rates may render an overall difference in height of the conductive layers 183-1 and 183-2, thereby enabling use of two different metallization layers (e.g., the pad structure 160-1 of the metallization layer 165-1 and the pad structure 160-2 of the metallization layer 165-2) to form pillar bump structures having a common bond line.

As further shown in FIG. 6D, the process 600 includes forming solder-based layers 620 (e.g., the solder-based layers 620-1 and 620-1) in the openings 615-1 and 615-2. In some implementations, techniques to form the solder-based layers 620-1 and 620-2 include a semiconductor manufacturing tool (e.g., a deposition tool) performing an electroplating operation that simultaneously forms the solder-based layers 620-1 and 620-2 in the openings 615-1 and 615-2. In some implementations and using techniques similar to those described in connection with FIG. 6C, a thickness of the mask structure 610 and/or the openings 615-1 and 615-2 is increased prior to formation of the solder-based layers 620-1 and 620-2.

As shown in FIG. 6E, the process 600 includes removing the mask structure 615 and portions of the seed layer 185 to form the pillar structures 180-1 and 180-2. In some implementations, techniques to remove the mask structure 610 may include a semiconductor tool (e.g., a wet strip tool) performing a stripping operation to remove the mask structure 610. In some implementations, techniques to remove portions of the seed layer 185 include a semiconductor tool (e.g., an etch tool) performing an etching operation to remove portions of the seed layer 185 and leave the seed layers 185-1 and 185-2 (e.g., segments of the seed layer 185).

As shown in FIG. 6F, the process 600 includes forming the bump structures 175-1 and 175-2 from the solder-based-layers 620-1 and 620-2. In some implementations, techniques to form the bump structures 175-1 and 175-2 include a semiconductor manufacturing tool (e.g., a reflow oven) performing a reflow operation at an elevated temperature to form the bump structures 175-1 and 175-2 from the solder-based-layers 620-1 and 620-2. As shown in FIG. 6F, an apex of the bump structure 175-1 and an apex of the bump structure 175-2 may have a substantially similar coplanarity D10.

As shown in FIG. 6G, the process 600 includes joining the die 115-5 with the die 115-4 using the pillar bump structures 170-1 and 170-2. In some implementations, techniques to join the die 115-5 with the die 115-4 include a combination of semiconductor manufacturing tools (e.g., a pick-and-place tool, a reflow oven) performing a combination of operations to form the bond region 145 and join the die 115-5 with the die 115-4.

The process 600 described in connection with FIGS. 6A through 6G describes formation of two sets of the pillar bump structures 170 (e.g., sets of the micron-pillar bump structures 170-1 and 170-2) that are formed over and/or on two, respective metallization layers 160 (e.g., the metallization layers 165-1 and 165-2) and that have two, respective sets of critical dimensions. However, and in some implementations, one or more operations described in connection with FIGS. 6A through 6G may be repeated and/or modified to form more than two sets of the pillar bump structures 170 that have more than two, respective sets of critical dimensions over and/or on more than two, respective metallization layers 160.

As indicated above, the process 600 described in connection with FIGS. 6A through 6G is provided as an example. Other examples may differ from what is described with respect to FIGS. 6A through 6G.

In process steps of FIGS. 6A through 6G that describe forming material, such material may be formed, for example, using chemical vapor deposition, atomic layer deposition, physical vapor deposition, electroplating, or another deposition operation. In process steps of FIGS. 6A through 6G that describe removing material, such material may be removed, for example, using a wet etching operation (e.g., wet chemical etching), a dry etching operation (e.g., plasma etching), an ion etching operation (e.g., sputtering or reactive ion etching), atomic layer etching, or another etching operation.

In some implementations, an apparatus includes an interconnect array structure, comprising a first metallization layer comprising a first pad structure; a second metallization layer comprising a second pad structure; at least one dielectric layer between the first metallization layer and the second metallization layer; a first pillar bump structure connected with the first pad structure, comprising: a first bump structure having a first volume; and a second pillar bump structure connected with the second pad structure, comprising: a second bump structure having a second volume that is greater than the first volume.

In some implementations, an apparatus includes a first semiconductor die, comprising: a multi-layer stack; a first pillar bump structure that extends away from a first metallization layer in the multi-layer stack to a first height; and a second pillar bump structure that extends away from a second metallization layer in the multi-layer stack to a second height, wherein the second height is greater than the first height; and a second semiconductor die joined with the first semiconductor die, comprising: a first pad structure having a first outer surface that joins with the first pillar bump structure; and a second pad structure having a second outer surface that joins with the second pillar bump structure.

In some implementations, a method includes forming a multi-layer stack including a first metallization layer, a second metallization layer, and at least one dielectric layer that is between the first metallization layer and the second metallization layer; forming a first cavity from a surface of the multi-layer stack to a first pad structure included in the first metallization layer; forming a second cavity from the surface of the multi-layer stack to a second pad structure included in the second metallization layer; forming, over the multi-layer stack, a mask with a first opening above the first cavity and a second opening above the second cavity; forming a first pillar structure in the first opening and the first cavity; forming a second pillar structure in the second opening and the second cavity, forming a first bump structure having a first volume on the first pillar structure; and forming a second bump structure having a second volume on the second pillar structure, wherein the second volume is greater than the first volume.

In some implementations, a method includes forming, as part of a first semiconductor die, a multi-layer stack including a first metallization layer, a second metallization layer, and at least one dielectric layer that is between the first metallization layer and the second metallization layer; forming a first pillar bump structure over a first pad structure included in the first metallization layer, wherein forming the first pillar bump structure includes forming a first bump structure having a first apex; forming a second pillar bump structure over a second pad structure included in the second metallization layer, wherein forming the second pillar bump structure includes forming a second bump structure having a second apex that is approximately coplanar with the first apex; and joining the first semiconductor die with a second semiconductor die using the first pillar bump structure and the second pillar bump structure.

In some implementations, a method includes receiving a semiconductor die including a first pillar bump structure and a second pillar bump structure, wherein the first pillar bump structure extends from a first metallization layer of the semiconductor die and includes a first bump structure having a first volume, and wherein the second pillar bump structure extends from a second metallization layer of the semiconductor die and includes a second bump structure having a second volume that is greater than the first volume; and joining the semiconductor die with pad structures of an apparatus using first pillar bump structure and the second pillar bump structure.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
an interconnect array structure, comprising:
a first metallization layer comprising a first pad structure;
a second metallization layer comprising a second pad structure;
at least one dielectric layer between the first metallization layer and the second metallization layer;
a first pillar bump structure connected with the first pad structure, comprising:
a first bump structure having a first volume; and
a second pillar bump structure connected with the second pad structure, comprising:
a second bump structure having a second volume that is greater than the first volume.

2. The apparatus of claim 1, wherein the first pillar bump structure comprises a first pillar structure that extends away from the first metallization layer to a first height, and wherein the second pillar bump structure comprises:
a second pillar structure that extends away from the second metallization layer to a second height,
wherein the second height is greater than the first height.

3. The apparatus of claim 2, wherein the first pillar structure or the second pillar structure comprises:
nickel,
copper,
aluminum,
gold, or
silver.

4. The apparatus of claim 1, wherein the first pillar bump structure comprises a first bump structure that extends away from a first pillar structure to a first height, and wherein the second pillar bump structure comprises:
a second bump structure that extends away from a second pillar structure to a second height,
wherein the second height is greater than the first height.

5. The apparatus of claim 1, wherein the first pillar bump structure comprises a first bump structure having a first width, and wherein the second pillar bump structure comprises:
a second bump structure having a second width,
wherein the second width is greater than the first width.

6. The apparatus of claim 1, wherein the first pillar bump structure extends away from first metallization layer to a first overall height, and
wherein the second pillar bump structure extends away from the second metallization layer to a second overall height,
wherein the second overall height is greater than the first overall height.

7. The apparatus of claim 1, wherein the first pillar bump structure is configured as a data input/output connection structure.

8. The apparatus of claim 1, wherein the second pillar bump structure is configured as a power signal connection structure.

9. An apparatus, comprising:
a first semiconductor die, comprising:
a multi-layer stack;
a first pillar bump structure that extends away from a first metallization layer in the multi-layer stack to a first height; and
a second pillar bump structure that extends away from a second metallization layer in the multi-layer stack to a second height,
wherein the second height is greater than the first height; and
a second semiconductor die joined with the first semiconductor die, comprising:
a first pad structure having a first outer surface that joins with the first pillar bump structure; and
a second pad structure having a second outer surface that joins with the second pillar bump structure.

10. The apparatus of claim 9, wherein the first metallization layer or the second metallization layer comprises:
nickel,
copper,
aluminum,
gold, or
silver.

11. The apparatus of claim 9, wherein the first outer surface and the second outer surface are approximately coplanar.

12. The apparatus of claim 9, wherein the first pillar bump structure comprises a first electromigration lifetime, and
wherein the second pillar bump structure comprises:
a second electromigration lifetime that is greater than the first electromigration lifetime.

13. The apparatus of claim 9, wherein the first pillar bump structure or the second pillar bump structure comprises:
a pillar structure comprising:
a conductive layer that is on a seed layer.

14. The apparatus of claim 9 wherein the first pad structure encompasses a first area, and
wherein the second pad structure encompasses a second area that is different than the first area.

15. The apparatus of claim 9, wherein the first pillar bump structure is configured as a clocking signal connection structure.

16. The apparatus of claim 9, wherein the second pillar bump structure is configured as a ground signal connection structure.

17. A method, comprising:
forming a multi-layer stack including a first metallization layer, a second metallization layer, and at least one dielectric layer that is between the first metallization layer and the second metallization layer;
forming a first cavity from a surface of the multi-layer stack to a first pad structure included in the first metallization layer;
forming a second cavity from the surface of the multi-layer stack to a second pad structure included in the second metallization layer;
forming, over the multi-layer stack, a mask with a first opening above the first cavity and a second opening above the second cavity;
forming a first pillar structure in the first opening and the first cavity;
forming a second pillar structure in the second opening and the second cavity, forming a first bump structure having a first volume on the first pillar structure; and
forming a second bump structure having a second volume on the second pillar structure,
wherein the second volume is greater than the first volume.

18. The method of claim 17, wherein forming the first pillar structure includes:
forming a seed layer in the first cavity.

19. The method of claim 17, wherein forming the second pillar structure includes:
forming a seed layer in the second cavity.

20. The method of claim 17, wherein forming the first pillar structure and the second pillar structure includes:
forming the pillar structure and the second pillar structure using at least one electroplating operation that simultaneously forms respective portions of the first pillar structure and the second pillar structure.

21. The method of claim 20, wherein simultaneously forming the respective portions of the first pillar structure and the second pillar structure includes:
simultaneously forming the respective portions at different electroplating growth rates.

22. A method, comprising:
forming, as part of a first semiconductor die, a multi-layer stack including a first metallization layer, a second metallization layer, and at least one dielectric layer that is between the first metallization layer and the second metallization layer;
forming a first pillar bump structure over a first pad structure included in the first metallization layer,
wherein forming the first pillar bump structure includes forming a first bump structure having a first apex;
forming a second pillar bump structure over a second pad structure included in the second metallization layer,
wherein forming the second pillar bump structure includes forming a second bump structure having a second apex that is approximately coplanar with the first apex; and
joining the first semiconductor die with a second semiconductor die using the first pillar bump structure and the second pillar bump structure.

23. The method of claim 22, wherein forming the second pillar bump structure includes:
forming at least a portion of a pillar structure in a cavity that penetrates through the dielectric layer.

24. The method of claim 22, wherein forming the first bump structure and the second bump structure includes:
simultaneously depositing a solder-based material for the first bump structure and the second bump structure using an electroplating operation.

25. The method of claim 22, wherein forming the first bump structure and the second bump structure includes:
simultaneously forming the first apex and the second apex using a reflow operation.
